(19) United States
(12) Patent Application Publication
(10) Pub. No.: US 2012/0025241 A1
(43) Pub. Date: Feb. 2, 2012

(54) SURFACE MOUNTED LED PACKAGING STRUCTURE AND METHOD BASED ON A SILICON SUBSTRATE

(75) Inventors: Guowei David XIAO, Guangzhou City (CN); Zhaoming ZENG, Guangzhou City (CN); Haiying CHEN, Guangzhou City (CN); Yugang ZHOU, Guangzhou City (CN); Yu HOU, Guangzhou City (CN)

(73) Assignee: APT ELECTRONICS LTD., Guangzhou City (CN)

(21) Appl. No.: 13/019,508

(22) Filed: Feb. 2, 2011

(30) Foreign Application Priority Data
Jul. 30, 2010 (CN) 201010243383.7

(51) Int. Cl. H01L 33/58

(52) U.S. Cl. 257/98; 438/27; 257/E33.073

(57) ABSTRACT

A surface mounted LED packaging structure based on a silicon substrate includes the silicon substrate, an LED chip, an annular convex wall and a lens. The silicon substrate has an upper surface of planar structure and without grooves. An oxide layer covers the upper surface of the silicon substrate. Metal electrode layers are arranged in the upper surface of the oxide layer, and the upper surfaces of the metal electrode layers are arranged with metal bumps. Vias through the silicon substrate are provided under the metal electrode layers. An insulating layer covers the inner wall of the vias and a part of the lower surface of the silicon substrate. A metal connection layer covers the insulating layer surface within the vias. Two conductive metal pads are respectively arranged under the lower surface of the silicon substrate and insulated from the silicon substrate. A heat conduction metal pad is arranged on the lower surface of the silicon substrate. The LED chip is flip-chip mounted on the silicon substrate. The annular convex wall and the lens cause the LED chip and the metal electrode layers therein to be isolated from environment. The structure of the present invention has its advantages of good heat dissipation effect and small volume, while packaging without gold wires makes the structure highly reliable and achieves large-scale production of wafer level, resulting in the reduction of the packaging cost.

### CROSS-REFERENCE TO RELATED APPLICATION

The present application claims priority of Chinese Patent Application CN201010243383.7 filed Jul. 30, 2010, the entire contents of which is incorporated herein by reference.

### FIELD OF THE INVENTION

The present invention belongs to the field of manufacturing a light emitting device, and relates to an LED packaging structure and method based on a silicon substrate.

### BACKGROUND OF THE INVENTION

The light emitting diode (LED) source has several advantages of high efficiency, long life and no harmful substances such as Hg and the likes. With the rapid development of LED technology, the LED's properties, such as brightness, lifetime and the likes, have been greatly improved, such that it has found an increasing application in a variety of areas ranging from outdoor lighting such as street lamps to indoor lighting such as decorative lights, in which LED is used or replaced as a light source.

The LED packaging structure of surface mounted type (SMD) has become a major form of package for its advantages of application convenience and small volume. Refer to FIG. 1, which is a surface mounted LED structure commonly used in prior art, including a packaging bracket 100 and an LED chip 200 mounted in the packaging bracket 100 by die attach process. Metal leads 500 are arranged on the surface of the packaging bracket 100. Electrodes 400 are arranged on the leads 500 on both sides of the LED chip 200. The positive and negative electrodes of the LED chip 200 are electrically connected to the electrodes 400 on the packaging bracket 100 by metal wires 300, respectively. Through phosphor coating and colloid encapsulating processes, an encapsulant colloid 600 is filled above the LED chip 200, thereby completing the packaging of the LED chip 200. However, there are the following problems with this present surface mounted LED structure: because the packaging bracket 100 is formed by a metal bracket being used as the substrate and then being cut after a colloid is encapsulated by means of plastic injection grooves or molded shape, it results in poor heat resistance, non-ideal heat dissipation and difficult miniaturization. Moreover, because the upper surface of the LED chip 200 is mounted and the structure of gold wires 300 for connecting electrodes is used, the connection failure of gold wires is often the failure mode mostly occurred during the production and use of LED. In addition, the upper surface mounted LED chip 200 dissipates heat through sapphire and thus has poor heat dissipation effect.

To address the problems existing in the above packaging bracket, a better approach is to use a silicon substrate directly as the package substrate of the LED chip. At present, the products of SMD structure based on the silicon substrate still cannot enjoy mass sales and applications in practice, and only some related patents are reported. The following process is mostly used by them: dig a deep groove on the upper surface of the silicon wafer, then dig vias in the groove, connect the electrode in the groove on the upper surface to the lower surface, and form a SMD packaging form; embed the LED chip in the silicon groove, and fill the groove with phosphor and an encapsulant colloid at the time of packaging. Furthermore, face-up chips of gold wire bonding are commonly used, while the flip-chip structure is partly used. With reference to FIG. 2, the packaging structure includes a silicon substrate 10, an LED chip 20 and a package colloid 30, wherein the upper surface of the silicon substrate 10 has a deep groove, the LED chip 20 is flip-chip mounted in the deep groove of the silicon substrate 10. Vias 50 are provided in the groove of the silicon substrate 10 corresponding to the positive and negative electrodes of the LED chip 20. The lower surface of the silicon substrate 10 corresponding to the vias 50 has conductive pads 60, to which the LED chip 20 is electrically connected by the leads provided in the vias 50. The package colloid 30 is formed by filling the deep groove with phosphor and the encapsulant colloid. There are the following disadvantages of this kind of structure. It is required to dig a large and deep groove on the upper surface the silicon wafer and to subject the silicon wafer to corrosion for a long time, with the process complex and the cost higher. Simultaneously with the groove deep, the difficulty in its internal wiring is increased. Especially if the flip chip is used, it is required to make metal bumps on the electrode of the groove. Furthermore, because there is the deep groove on the upper surface of the silicon substrate, it is not easy to integrate LED's peripheral circuits (such as anti-static protection circuit, driver circuit, etc.) in the silicon substrate, with the application prospects limited. In addition, the number of chips placed in the groove is limited by the size of the groove, thereby not easy to achieve multi-chip modules.

### SUMMARY OF THE INVENTION

The object of the invention is to overcome the shortcomings and deficiencies of prior art to provide a surface mounted LED structure with good thermal performance, process simplicity, low cost and controllable quality

Meanwhile, the present invention also provides a packaging method for said LED packaging structure.

A surface mounted LED packaging structure based on a silicon substrate includes the silicon substrate, an LED chip, an annular convex wall and a lens. Said silicon substrate has an upper surface of planar structure and without grooves, an oxide layer covers the upper surface of the silicon substrate, and two metal electrode layers for connecting positive and negative electrodes respectively, are arranged in the upper surface of the oxide layer and insulated from each other, and the upper surfaces of said metal electrode layers are arranged with metal bumps respectively; vias through the silicon substrate are respectively provided in the corresponding silicon substrate under the metal electrode layers; an insulating layer covers the inner wall of said vias and a part of the lower surface of the silicon substrate; a metal connection layer covers the insulating layer surface within the vias; two conductive metal pads are respectively arranged on the lower surface of the silicon substrate and insulated from the silicon substrate by the insulating layer, the conductive metal pads having a position corresponding to that of the vias and electrically connected to the metal electrode layers on the upper surface of the silicon substrate by the metal connection layer within the vias; and a heat conduction metal pad is arranged between the two conductive metal pads on the lower surface of the silicon substrate, with no insulating layer between the silicon substrate and the heat conduction metal pad. Said annular convex wall is arranged on the upper surface of the silicon substrate to form an enclosed area, and said LED chip are arranged within the enclosed area. Said lens is formed by directly shaping a liquid colloid due to restriction of the surface tension of the annular convex wall, and insolates the LED chip and the metal electrode layers therein from environment.

A surface mounted LED packaging method based on silicon substrate includes the steps of

Step S1: growing an epitaxial wafer with multiple layers of GaN on a sapphire substrate, and through lithography, etching, metal layer deposition and passivation layer protection process steps, etc., forming P and N electrodes and metal pads on the electrodes in an LED chip;

Step S2: on the silicon substrate, forming an oxide layer on an upper surface of the silicon substrate surface by thermal oxidation process firstly, and then forming metal electrode layers on the surface of the oxide layer by evaporation, sputtering or electroplating process, and then forming the metal electrode layers as the connections and pattern corresponding to the LED chip by lithography, corrosion or lift-off process, and finally forming metal bumps on the upper surfaces of the metal electrode layers by electroplating, evaporation or metal wire bumping method;

Step S3: forming the pattern of vias position in the lower surface of the substrate, and then subjecting the silicon substrate to dry etching or wet etching to form vias through the silicon substrate and the oxide layer on the upper surface thereof; then forming an insulating layer on the inner side of the vias and the lower surface of the silicon substrate; finally forming a metal connection layer in the insulating layer surface on the inner side of the vias, forming conductive metal pads on the insulating layer in the lower surface of the silicon substrate, and forming a heat conduction metal pad on the lower surface of the silicon substrate between two conductive metal pads, with no insulating layer between said heat conduction metal pad and the silicon substrate;

Step S4: flip-chip mounting the LED chip to said silicon substrate and connecting the metal pads corresponding to positive and negative electrodes on the LED chip with the metal bumps on the silicon substrate respectively.

Further, prior to the step S4, the method also includes the step of coating a dielectric layer on the upper surface of the silicon substrate and then subjecting exposure and development to form an annular convex wall.

Further, prior to the step S4, the method also includes the step of dispensing a colloid above the silicon substrate in said annular convex wall and then curing the colloid to form a lens by baking.

Compared to prior art, the packaging structure of the present invention has good heat dissipation effect and small volume; meanwhile packaging without gold wires makes the structure highly reliable. The LED chip is directly flip-chip mounted in the surface of the silicon substrate without the step of digging deep grooves in the silicon wafer surface, thereby reducing process costs and process difficulty. Meanwhile, the LED chip can be easily arranged in the upper surface of the silicon wafer, and the connection and package of multi-chip modules can be achieved arbitrarily and conveniently. A method of fabricating the annular convex wall on the upper surface of the silicon wafer is used to achieve the formation of better lenses directly by package dispensing, with lower cost than traditional molded lenses.

In order to more clearly understand the present invention, the implementations of the invention are set forth in conjunction with the drawings hereinafter.

### BRIEF DESCRIPTION OF THE ACCOMPANYING DRAWINGS

FIG. 1 is a schematic view of a surface mounted LED structure commonly used in prior art.

FIG. 2 is a schematic view of a packaging structure which uses a silicon substrate as the packaging substrate of the LED chip in prior art.

FIG. 3 is a cross section schematic view of LED packaging structure based on the silicon substrate of the invention.

FIG. 4 is a top view of FIG. 3.

FIG. 5 is a bottom view of FIG. 3.

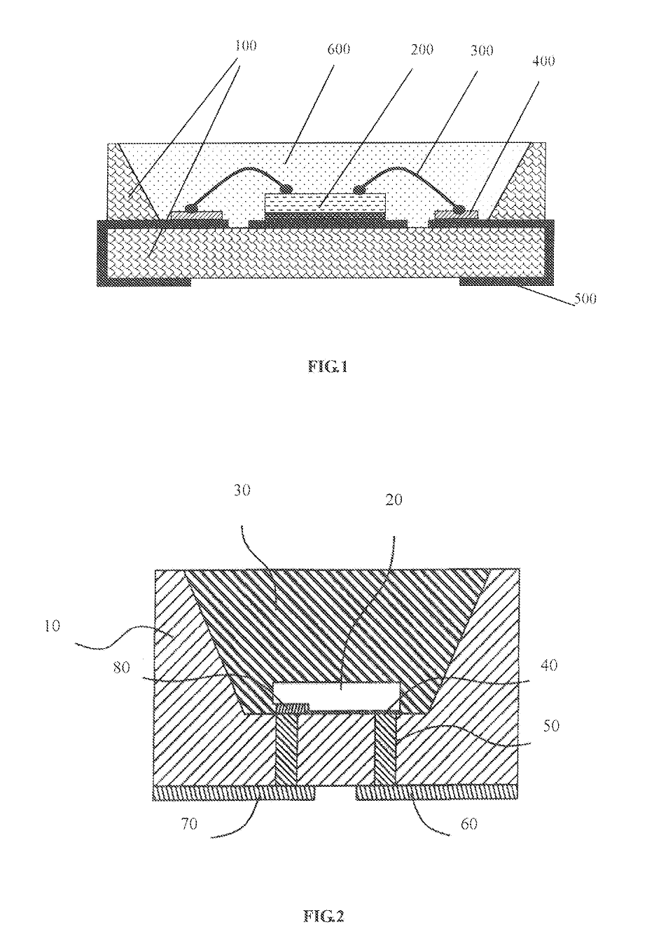

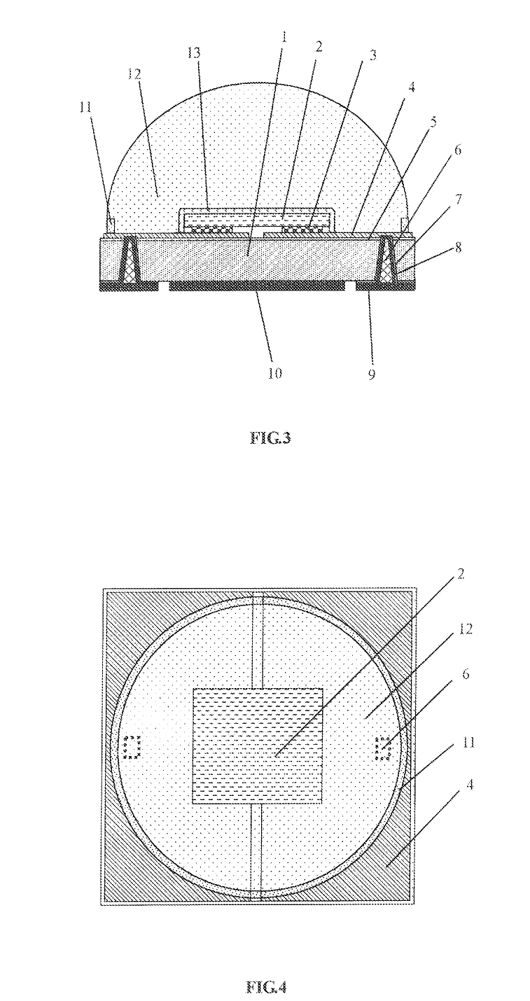

### DETAILED DESCRIPTION OF PREFERRED EMBODIMENTS

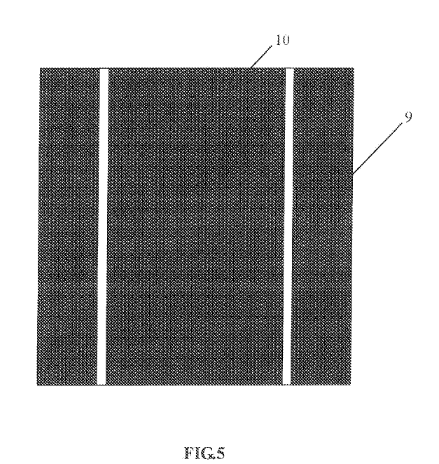

Now refer to FIGS. 3, 4 and 5, which are cross-section schematic view, top view and bottom view of the LED packaging structure based on the silicon substrate of the present invention, respectively. The LED packaging structure includes the silicon substrate 1, an LED chip 2 and a lens 12. In particular, the silicon substrate 1 has an upper surface of planar structure and without grooves. The upper surface of the silicon substrate 1 is covered by an oxide layer 5. Two metal electrode layers 4 for connecting positive and negative electrodes respectively are arranged in the upper surface of the oxide layer 5 and insulated from each other. The upper surfaces of the metal electrode layers 4 are respectively arranged with metal bumps 3. The LED chip 2 is flip-chip mounted on the silicon substrate 1, and the positive and negative electrodes of the LED chip 2 are respectively connected to the metal bumps 3 and thus connected to the metal electrode layers 4. Vias 6 through the upper and lower surfaces of the silicon substrate are provided respectively in the corresponding silicon substrate 1 under the metal electrode layers 4 on two sides of the LED chip 2. An insulating layer 7 covered the inner wall of the vias 6 and the lower surface of the silicon substrate. A metal connection layer 8 covered the surface of the insulating layer 7 within the vias 6. Two conductive metal pads 9 are respectively arranged under the lower surface of the silicon substrate 1 and are insulated from the silicon substrate 1 by the insulating layer 7, which have a position corresponding to that of the vias 6 and are connected to the metal electrode layers 4 on the upper surface of the silicon substrate 1 by the metal connection layer 8 within the vias 6. A heat conduction metal pad 10 is arranged between the conductive metal pads 9 and positioned on the lower surface of the corresponding silicon substrate 1 just below the LED chip 2, with no insulating layer between the heat conduction metal pad 10 and the silicon substrate 1. The upper surface of the LED chip 2 is coated with a layer of phosphor 13. An annular convex wall 11 is provided on two sides of the two vias 6 on the upper surface of the silicon substrate 1, which provides a confined space for the lens 12. The lens 12 causes the LED chip 12 and the metal wiring therein to be isolated from environment.

In particular, the material of said metal bumps 3 can be single material, multi-layer material or alloy of lead, tin, gold, nickel, copper, aluminum, indium.

The material of said conductive metal pads 9 and heat conduction metal pad 10 can be single material, multi-layer material or alloy of nickel, gold, silver, aluminum, titanium, tungsten, cadmium, vanadium, platinum and the likes.

Said annular convex wall 11 has a height between 10 um and 500 um. The material used in said annular convex wall 11 can be metal, oxide, nitride, polyimide, or photoresist permanently usable after being cured, etc.

The material of said lens 12 is a transparent resin or silicone, or can be a resin or silicone mixed with graininess phosphor, or is composed of two layers of material: the first layer is a colloid mixed with phosphor or a solid sheet of phosphor, and the second layer is a transparent resin or silicone.

Said insulating layer 7 can be polyimide, silicon oxide, silicon nitride, or photoresist permanently usable after being cured, etc.

The steps of manufacturing the LED packaging structure of the invention are described in detail as follows:

Step S1: the LED chip 2 is manufactured. In particular, an epitaxial wafer with multiple layers of GaN is grown on a sapphire substrate, and P and N electrodes and metal pads on the electrodes are formed in the LED chip after lithography, etching, metal layer deposition and passivation layer protection and other process steps. After grinded and polished, the wafer is diced into single LED chip 2.

Step S2: an oxide layer 5, metal electrode layers 4 and metal bumps 3 are formed the silicon substrate. In particular, an oxide layer 5 of certain thickness is formed on the upper surface of the silicon substrate wafer by thermal oxidation process for semiconductor production firstly. Then, metal electrode layers 4 are formed on the surface of the oxide layer 5 by evaporation, sputtering or electroplating process etc. Then the metal electrode layers 4 are formed as the connections and pattern corresponding to the LED chip by lithography, corrosion or lift-off process, etc. Finally the metal bumps 3 are formed on the upper surfaces of metal electrode layers 4 by means of electroplating, evaporation or metal wire bumping, etc.

Step S3: vias 6 are formed in the silicon substrate 1. In particular, the lower surface of silicon wafer is grinded to required thickness. Then, the lower surface of silicon wafer is subjected to dielectric layer deposition, coating, exposure, development, erosion processes, etc., forming the pattern of vias position. Then by using the dielectric layer or photoresist as mask layer, the silicon is subjected to dry etching or wet etching, thereby forming vias 6. Said vias 6 are through the oxide layer 5 on the upper surface of the silicon substrate 1.

Step S4: an insulating layer 7 is formed in the inner side surface of the vias 6 and the lower surface of the silicon substrate 1. In particular, an insulating layer is formed in the vias 6 and the lower surface of the silicon substrate 1 by means of electroplating or spray coating. By exposure and development, an open-hole is formed in the vias for connection to the metal on the upper surface of the silicon substrate, while the insulating layer corresponding to a heat conduction metal pad 10 in the lower surface of the silicon substrate is removed to retain the insulating layer at two conductive metal pads 9.

Step S5: a metal connection layer 8, conductive metal pads 9 and a heat conduction metal pad 10 are formed. In particular, by means of electroplating and electroless plating, etc., the metal connection layer 8 is formed in the surface of the insulating layer 7 in the vias 6, the conductive metal pads 9 are formed on the insulating layer in the lower surface of the silicon substrate 1, and the heat conduction metal pad 10 is formed in the lower surface of the silicon substrate 1 corresponding to the LED chip 2. The conductive metal pads 9 are electrically connected to the metal electrode layers 4 on the upper surface of the silicon substrate 1 by the metal connection layer 8.

Step S6: an annular convex wall 11 is formed. In particular, a dielectric layer is coated on the upper surface of the silicon substrate 1 and then subjected to exposure and development to form the annular convex wall 11 of required thickness. The dielectric layer can use polyimide, or photoresist permanently usable after being cured, etc.

Step S7: the LED chip 2 is flip-chip bonded to the front surface of the silicon substrate 1. Individual LED chip 2 is flip-chip bonded to the upper surface the silicon wafer by an automated flip-chip bonding equipment. The flip-chip bonding process is actually a bonding process of the metal bump 3 with the metal pads of P and N electrodes of the LED chip 2. The solder-reflow method, or a bonding process of applying ultrasonic wave after heated can be used.

Step S8: a phosphor layer 13 is coated on the surface of the LED chip 2. Phosphor particles are firstly mixed into a colloid to form a fluorescent colloid, and then a coating process is conducted. The coating method can be spray coating, brush coating or dispensing colloid, etc.

Step S9: a lens is formed. A colloid is dispensed above the silicon substrate 1 in the annular convex wall 11. The amount of the dispensed colloid is determined by the size of the chip and the viscosity of the colloid, such that the surface tension of the outer height of the annular convex wall 11 can confine the colloid not to extend outward. At the same time, an appropriate amount of the colloid can bulge itself upward close to hemispherical shape. Then, the colloid is cured by baking, i.e. to form the lens 12.

Compared to prior art, the present invention directly flip-chip mounts the LED chip in the surface of the silicon substrate without the step of digging deep grooves in the silicon wafer surface, thereby reducing process costs and process difficulty. Due to no grooves on the upper surface of the silicon substrate, it can be easily realized that the LED's peripheral circuits are integrated in the surface of the silicon substrate, such as anti-static protection circuit, LED constant current driver circuit, etc.; meanwhile the LED chip can be easily arranged in the upper surface of the silicon wafer, and the connection and package of multi-chip modules can be achieved arbitrarily and conveniently. The method of fabricating the annular convex wall on the upper surface of the silicon wafer is used to achieve uniform dispensing package and form better lenses, with lower cost than traditional molded lenses. The packaging structure of the present invention can be conveniently diced after all packaging procedures are completed on the entire silicon wafer, achieving LED package of wafer level and reducing the packaging cost. In addition, the invention uses a layer of silicon as the packaging substrate to export the heat generated by the LED chip directly through the silicon, with the thermal resistance relatively smaller. The flip-chip process is used to connect the LED to the silicon substrate directly through the metal bumps, which has better heat dissipation effect than face-up LED products that dissipate heat through sapphire. The entire packaging structure has not any gold wires, thereby reducing reliability issues due to connection failure of gold wires. The entire packaging structure has relatively smaller volume and is beneficial to the structural miniaturization of LED (especially the high-power LED) and its modules, and facilitates secondary optical designs in the subsequent lighting products.

In addition, the LED packaging structure based on the silicon substrate of the invention can also have a plurality of implementations. For example, the phosphor layer may not have to be arranged separately on the upper surface of the LED chip, but the lens is foamed by directly dispensing the transparent resin colloid or silicone, with a blue LED packaged; or phosphor particles is uniformly mixed with the encapsulant colloid, and then directly dispensed on the chip within the annulus of the silicon wafer surface, and baked and cured to form the lens. Alternatively, solid phosphor sheet already produced is first mounted onto the surface of the LED chip, and then the transparent encapsulant colloid is dispensed within the annulus of the silicon wafer surface to form the lens.

The present invention is not limited to the above implementations. If changes and variations of the invention are not departed from the spirit and scope of the invention, and these changes and variations fall within the scope of the claims of the invention and equivalent technology, then the present invention is also intended to encompass these changes and variations.

What is claimed is:

1. A surface mounted LED packaging structure based on a silicon substrate, comprising:
the silicon substrate, wherein said silicon substrate has an upper surface of planar structure and without grooves, an oxide layer covers the upper surface of the silicon substrate, and two metal electrode layers for connecting positive and negative electrodes respectively, are arranged in the upper surface of the oxide layer and insulated from each other, and the upper surfaces of said metal electrode layers are arranged with metal bump respectively; vias through the silicon substrate are respectively provided in the corresponding silicon substrate under the metal electrode layers; an insulating layer covers the inner wall of said vias and a part of the lower surface of the silicon substrate; a metal connection layer covers the insulating layer surface within the vias; two conductive metal pads are respectively arranged on the lower surface of the silicon substrate and insulated from the silicon substrate by the insulating layer, the conductive metal pads having a position corresponding to that of the vias and electrically connected to the metal electrode layers on the upper surface of the silicon substrate by the metal connection layer within the vias; and a heat conduction metal pad is arranged between the two conductive metal pads on the lower surface of the silicon substrate, with no insulating layer between the silicon substrate and the heat conduction metal pad;
an LED chip flip-chip mounted to the silicon substrate and having positive and negative electrodes respectively connected to two metal bumps;
an annular convex wall arranged on the upper surface of the silicon substrate to form an enclosed area, wherein said LED chip are arranged within the enclosed area;
a lens formed by directly shaping a liquid colloid due to restriction of the surface tension of the annular convex wall, and insolating the LED chip and the metal electrode layers therein from environment.

2. The packaging structure of claim 1, wherein said annular convex wall has a height between 10 um and 500 um.

3. The packaging structure of claim 1, wherein the material used in said annular convex wall is metal, oxide, nitride, polyimide, or photoresist permanently usable after being cured.

4. A surface mounted LED packaging method based on silicon substrate, comprising the steps of:
Step S1: growing an epitaxial wafer with multiple layers of GaN on a sapphire substrate, and through lithography, etching, metal layer deposition and passivation layer protection process steps, etc., forming P and N electrodes and metal pads on the electrodes in an LED chip;
Step S2: on the silicon substrate, forming an oxide layer on an upper surface of the silicon substrate surface by thermal oxidation process firstly, and then forming metal electrode layers on the surface of the oxide layer by evaporation, sputtering or electroplating process, and then forming the metal electrode layers as the connections and pattern corresponding to the LED chip by lithography, corrosion or lift-off process, and filially forming metal bumps on the upper surfaces of the metal electrode layers by electroplating, evaporation or metal wire bumping method;
Step S3: forming the pattern of vias position in the lower surface of the substrate, and then subjecting the silicon substrate to dry etching or wet etching to form vias through the silicon substrate and the oxide layer on the upper surface thereof; then forming an insulating layer on the inner side of the vias and the lower surface of the silicon substrate; finally forming a metal connection layer in the insulating layer surface on the inner side of the vias, forming conductive metal pads on the insulating layer in the lower surface of the silicon substrate, and forming a heat conduction metal pad on the lower surface of the silicon substrate between two conductive metal pads, with no insulating layer between said heat conduction metal pad and the silicon substrate;
Step S4: flip-chip mounting the LED chip to said silicon substrate and connecting the metal pads corresponding to positive and negative electrodes on the LED chip with the metal bumps on the silicon substrate respectively.

5. The packaging method of claim 4, further comprising prior to the step S4:
coating a dielectric layer on the upper surface of the silicon substrate and then subjecting exposure and development to form an annular convex wall.

6. The packaging method of claim 5, further comprising prior to the step S4:
dispensing a colloid above the silicon substrate in said annular convex wall, and then curing the colloid to form a lens by baking.
